(19) United States
(12) Patent Application Publication
(10) Pub. No.: US 2012/0086466 A1
(43) Pub. Date: Apr. 12, 2012

(54) Semiconductor test probe apparatus and method

(76) Inventor: Arlen Chou, Los Altos, CA (US)

(21) Appl. No.: 12/924,986

(22) Filed: Oct. 8, 2010

Related U.S. Application Data
(60) Provisional application No. 61/404,760, filed on Oct. 8, 2010.

(51) Int. Cl. G01R 31/26; G01R 1/073

(52) U.S. Cl. 324/755.11

(57) ABSTRACT

An improved probe card system includes a probe assembly having a cantilever probe with a contact arm integral with and extending from a distal end of the probe, wherein the contact arm is oriented substantially parallel to a die or other material to be tested. The contact arm may be an elongated tip of the probe configured to contact a bumped pad or other contact on an outer surface of the arm. Inherent cantilever action of the probe may translating to a scrubbing action of the side of a contact arm on a test pad or solder ball. Some embodiments employ two or more probes for Kelvin-type probing, and the contact arm at the end of the probe can incorporate a substantially straight arm or a bent arm to follow the contour of a solder bump.

### RELATED APPLICATIONS

This application claims priority under 35 U.S.C. §119 to U.S. Provisional application Ser. No. ______, titled “Semiconductor Test Probe Apparatus and Method”, filed on Oct. 9, 2009, which application is incorporated by reference herein in its entirety.

### TECHNICAL FIELD

The disclosed embodiments relate generally to systems and methods for testing semiconductor devices, and in particular to electrical test probes for testing semiconductor chips/die and wafers.

### BACKGROUND

Unless otherwise indicated herein, the approaches described in this section are not prior art to the claims in this application and are not admitted to be prior art by inclusion in this section.

Integrated circuits are made in a bulk parallel process by patterning and processing semiconductor wafers. Each wafer contains many identical copies of the same integrated circuit, sometimes referred to as a “die.” It may be preferable to test the semiconductor wafers before the die is cut into individual integrated circuits and packaged for sale. If defects are detected the defective die can be culled before wasting resources packaging a defective part. The individual die can also be tested after they have been cut into individual integrated circuits, either before or after being packaged (here “packaged” refers to the process of being connected to an electrical interconnect package that protects the die and allows for assembly onto a wiring board).

To test a wafer or an individual die, commonly called the device under test or DUT, a probe card is commonly used which comes into contact with the surface of the DUT. The probe card generally includes an XY array of individual probes that move in the Z direction to allow contact between each probe and a corresponding contact pad or bump on the die. An electrical interface of the card connects the card to a circuit test apparatus. When the probe card is brought in contact with the die pad, the Z-direction movement allows for a solid contact with the probe tip. The probe card ultimately provides an electrical interface that allows a circuit test apparatus to be temporarily connected to the DUT. This method of die testing is extremely efficient because many die can be tested at the same time. Existing probe and probe card system, methods and materials are described, for example, in U.S. Pat. No. 6,573,738 (titled “Multi-layered probe for a Probecard”), U.S. Pat. No. 4,764,722 (titled “Coaxial Probe”), U.S. Pat. No. 4,853,627 (titled “Wafer Probes”), U.S. Pat. No. 4,523,144 (titled “Complex Probe Card for Testing a Semiconductor Wafer”), U.S. Pat. No. 4,382,228 (titled “Probes for Fixed Point Probe Cards”), and U.S. Pat. No. 5,486,770 (titled “High Frequency Wafer Probe Apparatus and Method”), each of which are incorporated herein by reference.

Common types of probe designs or methods used to test a semiconductor die include vertical probes and cantilever probes. When probing a pad using a vertical probe method, the probe can intercept the pad surface vertically or nearly so. Some further mechanical structure associated with the probe provides a spring action. However, in this instance the cost and time associated with manufacture of this type of probe card is often prohibitive. As with any mechanical contact between two objects, material transfer can and often does take place during the testing process. This material may become deposited on the vertical probe needle. This material is often in the form of silicon oxide, a non-conductive material or a material of similar non-conductive nature. As this material builds, false failures of die on the wafer can be encountered as the buildup of non-conductive material leads to “high contact resistance failures”.

More clearly defined, the tester fails the die due to an incomplete electrical circuit between the tester and the die being tested. Often when the probe card is cleaned of this material build up, and the same die is tested, the result is a “passed” die. As the vertical probe card, by design, has no self cleaning, or scrub, built into it, the test operator must intermittently clean the probe card. This leads to a loss in active test time and in turn to a higher cost of test. Additionally, the “failed” die must be retested to capture any “false” failures due to the high contact resistance caused by the contamination. This again leads to longer test cycles and therefore added cost. However, in practice, the failed die are often not retested leading to actual good die to be discarded due to the high “contact resistance”. This in turn leads to lower test yields and higher per good die costs.

Another test method for “bumped” die is to use a standard cantilever probe system, for example such as system 10 illustrated in FIGS. 1A-C. A typical cantilever probe system 10 includes a probe 20 secured to a PCB board 14 by a ring 30, e.g. using epoxy 32. A tail or proximal end of the probe 20 connects to the underside of the board 14 by a solder point 38, and a beam or shaft portion 22 of probe extends at a downward angle from the board 14, e.g., toward a die 40 to be tested. A bent tip 26 of probe 20 angles further downward and is configured and dimensioned to contact a pad 42. Depending upon the desired application, tip 26 may be a very small and sharp, or may relatively large and blunt tip.

Although the inherent benefit of a cantilever probe is to impose a “scrub” into the contact action of the probe card, this scrub has been eliminated in the testing of bumped die. A reason for the elimination was the concern over the potential for the needle to over shoot the bump during test and lead to inadvertent test shorts or the needle scrubbing off the bump and landing on the active die surface damaging the die.

Therefore, an industry practice has been to either use the sharp tip or blunt tip methods for testing bumped die. In the case of the sharp tip, the probe wire tip is either a “sharp” or extremely small tip. A theory behind this method is that the needle pierces the solder bump and penetrates through oxide or non-conductive material built up on the solder bumps. The penalty of using this type of methodology is that the design of the probe card is extremely fragile. The needles tend to bend easily during the testing process which leads to premature failure of the probe card. This then leads to the added cost of either repairing probe cards or replacing damaged probe cards. Additional to the cost of the damaged probe cards, there is a factor of time lost during the testing process while a new probe card is sourced.

Compounding the potential dangers of using the “sharp” tip method of building probe cards, has been the recent global trend to move to “lead free” solder which has exacerbated the problems with this design. The chemical and physical structure of “lead free” solder bumps leads to an inconsistency of the hardness of the actual solder bump: some areas of the solder bumps are harder than others. As the “sharp” probe is designed to pierce the bump, problems arise if some needles in a probe array pierce the bumps and some are not able to, due to a hard bump. The needles which do not pierce the bump then often glance off the bump and do not make good electrical contact, due to any non-conductive material build up on the bump or needle itself.

An additional flaw in this traditional style of probe needle is that it has eliminated the actual scrubbing motion of a traditional cantilever needle. As the probe is designed to pierce and stick the bump material, transfer of any non-conductive material is not removed. Similar to the vertical style of probe card, the contaminated material is left to build up on the probes until an induced cleaning method is used to remove the said contaminants. The contaminants can lead to false negatives during the testing process leading to a lower test yield. If contaminants are believed to be leading to false negatives, testing is stopped and a cleaning procedure is implemented. This cleaning process is usually an aggressive process which can inadvertently damage the probe card. Even if the card is not damaged during the cleaning process, active test time is lost due to this added step. This action alone leads to higher test cost and a more expensive final product.

In some cases, to avoid the design flaws of the sharp tip method, a large blunt tip is used. The theory behind this method is that the tip will not penetrate the solder bump, therefore eliminate the potential of hitting hard solder bumps or areas of hard solder on the bump. Additionally, as the probe tip is substantially larger it is by design much stronger. The traditional design of this type of probe solution has been to compress or smash the solder bump. The reasoning behind this is that if the larger probe needle were to slide or scrub off of the bump, it may come into contact with one of the surrounding solder bumps, leading to a test short or contact the actual die surface leading to permanent damage of the die. Similar to the earlier described designs the larger tip was implemented in a fashion which eliminated the natural scrubbing action of a cantilever probe design, which contributes to the buildup of non-conductive materials on the probe tips.

These current testing methods and apparatus for probing bumped wafers include inherent problems. Probe cards built with conventional technologies either use a standard cantilever probe, with either a small pointed tip or a large blunt tip, or a vertical probe card technology. For example, neither cantilever probes with pointed or blunt tips, nor vertical probe cards, address inherent problem of build up of residual material during wafer testing. This build of materials in the form of contamination can lead to what is commonly referred to as “high contact resistance”. This is due to the loss of signal continuity which is created by the said build up of contamination. As the test process is an automated process, the system detects these as failures of the tested die. However, in most cases, if this contact resistance is addressed and the die is retested the failed die passes and becomes an acceptable device.

As the cleaning and retesting of silicon wafers and die is both time consuming and costly, often times the failed die is rejected and a lower than optimal test yield is accepted. The invention presented integrates a self cleaning scrub process which eliminates the contamination during the actual testing process. This leads to higher test yields and a lower test time.

Thus, there is a need for improved probe card systems and methods. The present invention solves these and other problems by providing a cantilever prove with an improved tip design that optimizes contact with the pad. Unlike previous designs for probe needles, this invention does not use the tip or end of a wire or assembly to make contact with the testing surface. Instead the rounded side of the wire is used as the contact surface, leading to a much more robust probe design.

### SUMMARY

Embodiments of the present invention provide improved semiconductor test probe apparatus and methods, including a scrub applied cantilever probe for testing a bumped semiconductor wafer. In one embodiment, an improved probe card system includes a probe assembly having a cantilever probe with a contact arm integral with and extending from a distal end of the probe, wherein the contact arm is oriented substantially parallel to a die or other material to be tested. In some embodiments, the contact arm is an elongated tip of the probe configured to contact a bumped pad or other contact on an outer surface of the arm. In some embodiments, the design of the invention is such that the inherent cantilever action of the probe is incorporated into the movement of the probe contact area, translating to a scrubbing action on the pad or solder ball. In a dual probe design, e.g., used in “Kelvin” type probing; the contact area can incorporate a substantially straight arm tip portion (sometimes referred to herein as a “Straight Arm”) or a bent tip to follow the contour of the solder bump, e.g., referred to herein as a “Halo Arm”. As the probe card moves up and down during the test process, the contact arms in the dual probe design may slide up and down around the solder bump. During such movement, contaminants and non-conductive materials may be scraped away from the contact surfaces of both the contact arm of the probe needle and the solder bump exposing clean material for good electrical contact.

### BRIEF DESCRIPTION OF THE DRAWINGS

For a better understanding of the nature and objects of the invention, reference should be made to the following detailed description taken in conjunction with the accompanying drawings, in which:

FIG. 1A is a cross-sectional view illustration of a typical cantilever probe card system known in the art for testing a semiconductor wafer or die.

FIG. 1B is a schematic top view illustration of the system of FIG. 1A, showing a single conventional cantilever probe in contact with a bumped pad of a wafer or die.

FIG. 1C is a schematic top view illustration of the system of FIG. 1A, showing a pair of conventional cantilever probes in contact with the bumped pad, in a method known as “Kelvin Probing”;

FIG. 2 is a cross-sectional side view illustration of a cantilever probe assembly according to an embodiment of the present invention, including a probe having a substantially horizontal contact arm;

FIG. 3 is a schematic top view illustration of the probe assembly of FIG. 2, having a substantially straight contact arm;

FIG. 4 is a schematic top view illustration of an alternative embodiment of the probe assembly of FIG. 2, having a halo-shaped contact arm;

FIG. 5A is a cross-sectional side view illustration of the probe assembly of FIG. 2, before contact with a bumped pad on a die;

FIG. 5B is a cross-sectional side view illustration of the probe assembly of FIG. 5A, at vertical displacement of the probe card to contact between the contact arm and the bumped pad;

FIG. 5C is a cross-sectional side view illustration of the probe assembly of FIGS. 5A and 5B at overdrive of the probe card, showing further contact of the contact arm against the bumped pad;

FIG. 6 is a schematic top view illustration of the another embodiment of the probe assembly of FIG. 2, having two probes with substantially straight contact arms;

FIG. 7 is a schematic top view illustration of the another embodiment of the probe assembly of FIG. 2, having two probes with halo-shaped contact arms;

FIG. 8A is a schematic end view illustration of the probe assembly of FIG. 6, before contact with a bumped pad on a die;

FIG. 8B a schematic end view illustration of the probe assembly of FIG. 8A, at vertical displacement of the probe card to contact between the contact arms and the bumped pad;

FIG. 8C is a schematic end view illustration of the probe assembly of FIGS. 8A and 8B at overdrive of the probe card, showing further contact of the contact arms against the bumped pad;

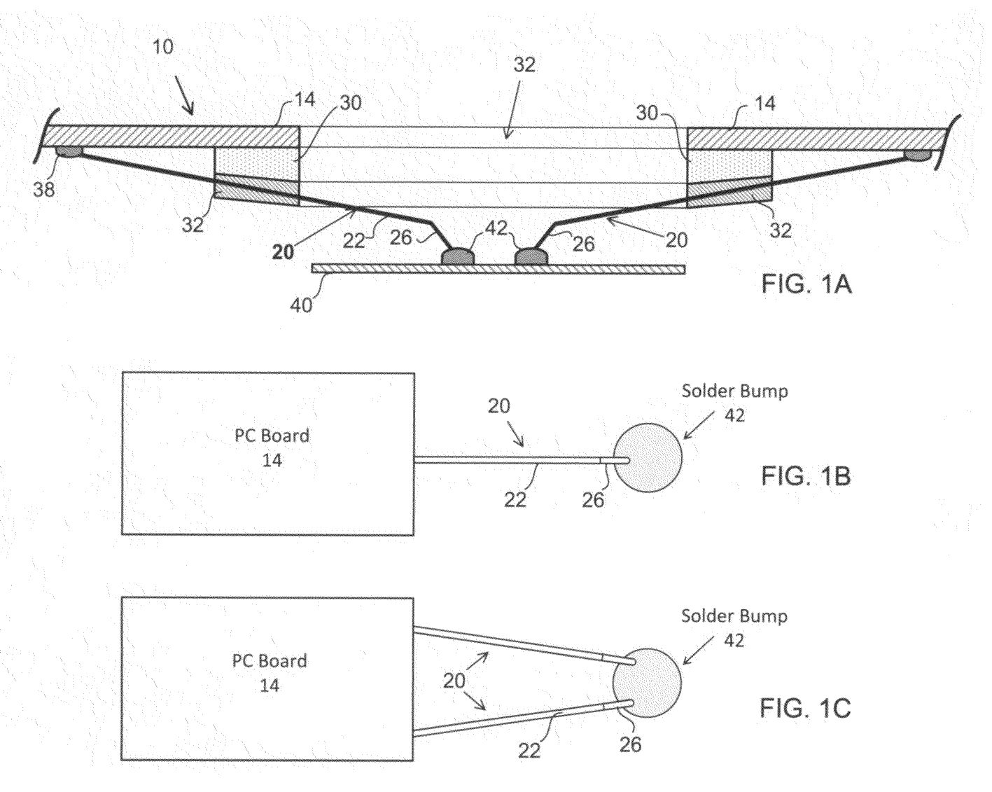

Like reference numerals refer to the same or similar components throughout the several views of the drawings.

### DESCRIPTION OF EMBODIMENTS

Described herein are apparatus and methods for testing semiconductor die and wafers. In the following description, for purposes of explanation, numerous examples and specific details are set forth in order to provide a thorough understanding of the present invention. It will be evident, however, to one skilled in the art that the present invention as defined by the claims may include some or all of the features in these examples alone or in combination with other features described below, and may further include modifications and equivalents of the features and concepts described herein.

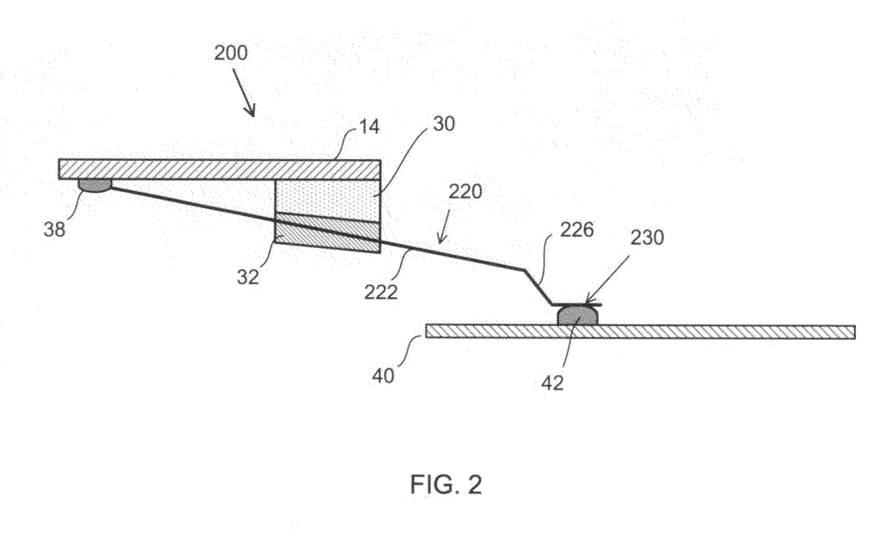

Referring to FIG. 2, a probe card system 200 comprises a probe assembly 220 attached to a surface of single or multi-layered PCB board 14 or other substrate. Probe assembly 220 includes an elongated cantilever probe 222 secured to the PCB board 14 by ring 30, e.g. using epoxy 32. A tail or proximal end of the probe 220 connects to the underside of the board 14, e.g., by a conductive solder point 38. A beam or shaft portion of probe 222 extends at a downward angle from board 14, e.g., toward a die 40, wafer or other device to be tested (e.g., a DUT). A bent portion 226 of probe 20 angles further downward and leads to a contact arm 230 configured and dimensioned to contact a conductive pad 42 of the die 40. Preferably, contact arm 230 is angled with respect to the bent portion 226 and/or the shaft 222 such that the outer surface of the probe (as opposed to the tip) contacts pad 42 when the card 200 is lowered onto the die 40 to be tested. In some embodiments, pad 42 is a bumped pad, e.g., comprise of solder material in electrical communication with a circuit in the die 40 or wafer. In some embodiments, contact arm 230 is substantially horizontal or parallel to a plane of the probe card 14 and/or the die 40, such that an outer edge of the tubular arm contacts pad 42 when assembly 200 is lowered wards the die to be tested 40. In some embodiments, bent portion 226 and contact arm 230 may be bent at gradual or curved angles rather than sharp angles as shown in the FIG. 2.

When assembly 200 is lowered, probe 222 is configured and dimensioned to contact and form an electrical connection between the device bond pads 42 or signal terminals on the die or chip to be tested 40 and test equipment in electrical communication with the probe card, e.g., through connection 38. Any desired number of probe assemblies 220 may be installed on the probe card system 200 in a pattern that match the pads deposited on the device 40. For example, in some embodiments the spacing between adjacent probe needles can be as tight as 20-30 microns or more. In some embodiments, there can be as many as a few thousand probe needles in the space of a few square centimeters on a probe card. Probe 222 may be comprised of any suitable material depending upon the desired application, e.g., tungsten, tungsten-rhenium, beryllium-copper, or Paliney™. In other embodiments, materials such as silver or exotic metal alloys or insulating materials may be employed.

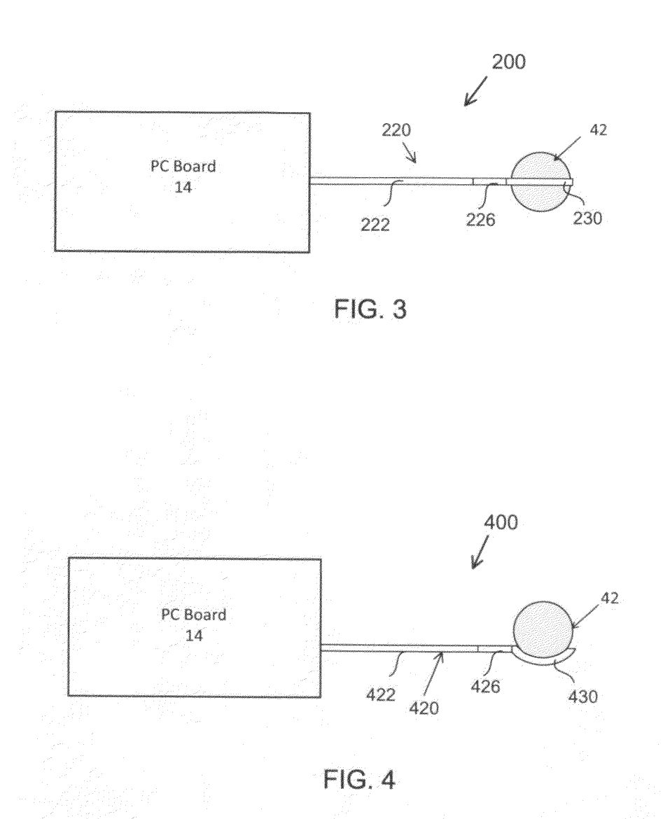

FIG. 3 is a schematic top view illustration of the probe assembly of FIG. 2, having a substantially straight contact arm according to one embodiment of the invention. In one embodiment, the elongated outer edge of substantially cylindrical or wire-shaped arm 230 of probe 222 contacts pad 42 to form an electrical connection between pad and probe 222.

In another embodiment as illustrated in FIG. 4, a probe assembly 420 includes a probe 422 and an angled portion 426 which may be similar to probe 222 and portion 226 of probe 222. In this embodiment, however, instead of substantially straight contact arm 230, a contact arm 430 having an arc or halo shape is employed. In some embodiments, halo-shaped arm 430 is configured and dimensioned to optimize surface contact area between the outer surface of arm 430 and a bumped pad 42.

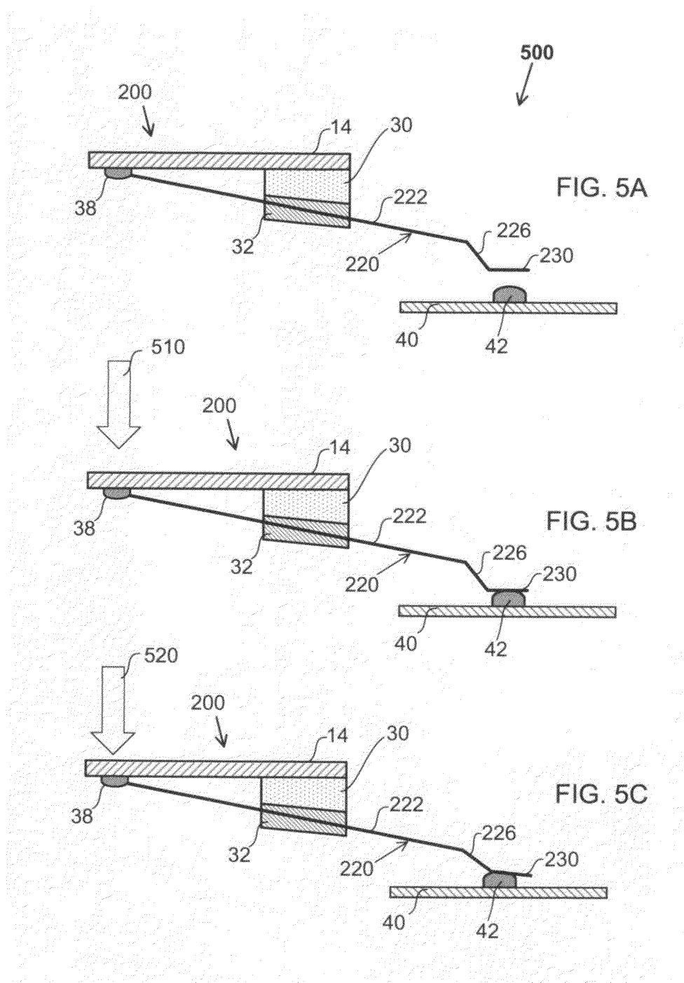

Turning now to FIGS. 5A-5C, a method 500 of testing a die or wafer comprises a probe card assembly such as assembly 200. FIG. 5A shows assembly 200 prior to contact between arm 230 and pad 42. As card assembly 200 is displaced toward the device to be tested 40, e.g., by a distance illustrated by 510 as shown in FIG. 5B, arm 230 of probe 222 comes into contact with pad 42. As shown in FIG. 5C, as card assembly 200 is further displaced toward device 40, e.g. as schematically illustrated by arrow 520, force imparted through probe 222 (e.g. a bending or moment force) and/or portion 226, translates to a longitudinal displacement or straight “scrubbing action” of arm 230 across the surface of pad 42. During such movement, contaminants and non-conductive materials may be scraped away from the contact surfaces of both the contact arm 230 of probe 222 and the solder bump 42, exposing clean material for improved electrical contact.

In other embodiments, a probe assembly such as assembly 420 having a curved or halo-shaped contact arm 430 may result in a broader scrubbing action in more than one dimension, e.g. combining a longitudinal and lateral scrubbing action across pad 42

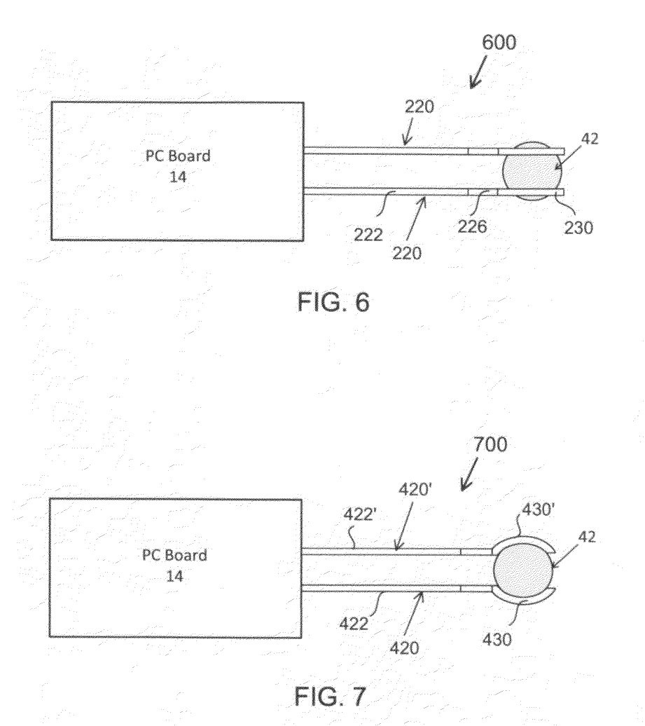

As shown FIG. 6, in some embodiments according to the present invention a probe card system 600 includes two or more probe assemblies 220, including probes 222 and contact arms 230 configured to contact a single pad 42. Such probe card systems 600 may be employed, for example, to perform “Kelvin probing” of a device to be tested.

Similarly, as shown in FIG. 7, a Kelvin probe system 700 employs two or more probes 420 and 420′ having opposing halo-shaped contact arms 430 and 430′ configured and dimensioned to optimize contact with pad 42, e.g., on substantially opposite sides of pad 42 as show. One skilled in the art will appreciate that the above examples are illustrative, and contact arms 230, 430 and 430′ may have different shapes or dimensions without departing from the scope of the invention.

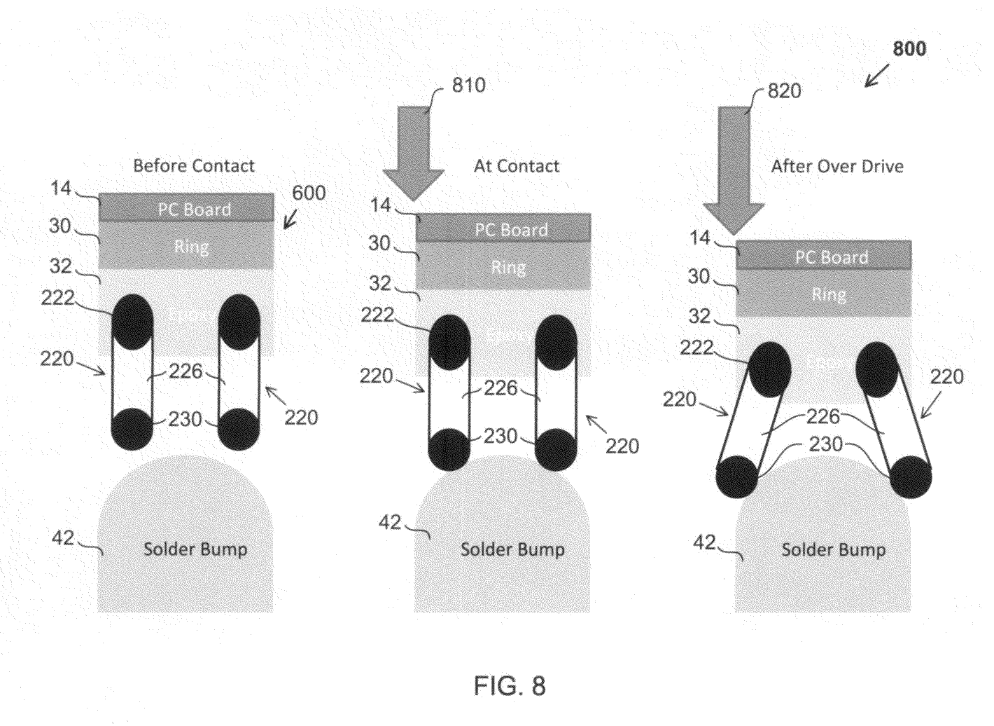

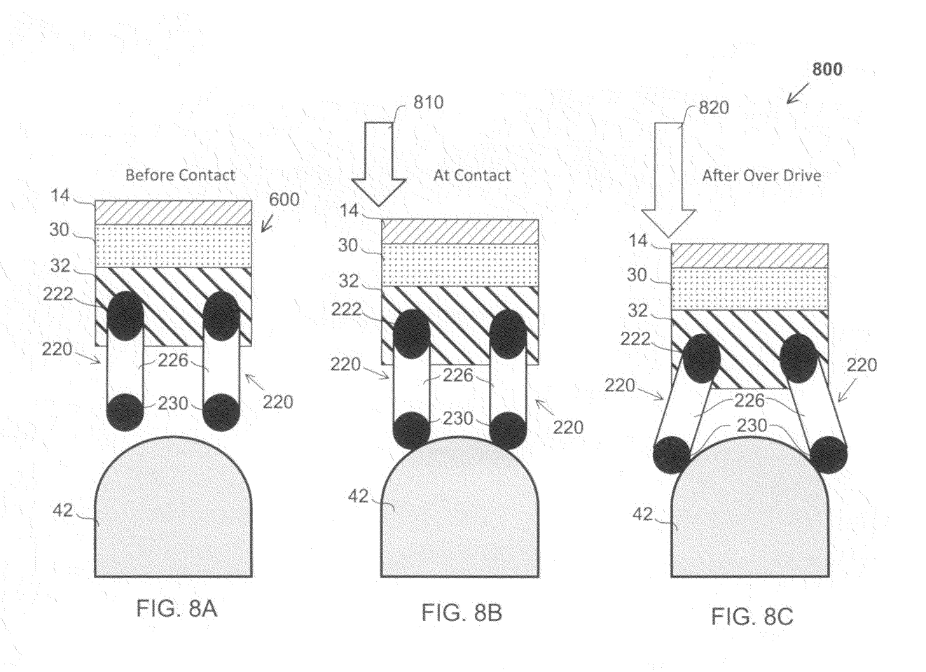

Referring now to FIGS. 8A-C, an example of a method of use 800 of a dual-probe assembly 220 Kelvin probe system 600 is illustrated. The left side of FIG. 8, labeled “Before Contact”, shows probes 222 before contact with a solder bump FIG. 8A is a schematic end view illustration of the probe assembly of FIG. 6, before contact with a bumped pad on a die 42. Then card 600 is lowered, e.g., by an amount illustrated by arrow 810, arms 230 of probes 222 contact an upper surface of bumped pad 42. As card 600 is lowered further, e.g. during “over drive” as illustrated by arrow 820, bent tip portions 226 cantilever probes 220 may bend substantially away each such that contact arms 230 remain in contact with bump 42 as they scrub down the sides of bump 42. As discussed above with respect to FIG. 5, this scrubbing action may serve to clean contact surface of bump 42 and/or arms 230 to help optimize electrical contact.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings and may be employed by those skilled in the art. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A probe card, comprising:
a circuit board; and
a probe assembly comprising at least one elongated probe having a shaft connected at a first end to an electrical contact on said circuit board and extending at an oblique angle from said circuit board, wherein
a second end of the probe opposite the first end comprises a contact arm bent with respect to the shaft such that the contact arm is substantially parallel to circuit board.

2. The probe card of claim 1, wherein the first end of the probe is connected to the contact on said circuit board by a solder point.

3. The probe card of claim 1, further comprising a ring disposed between the circuit board and the shaft of the probe, wherein the shaft is secured to said ring by an epoxy.

4. The probe card of claim 1, wherein the contact arm of said elongated probe has a substantially cylindrical shape.

5. The probe card of claim 4, wherein the contact arm is configured and dimensioned such that an outer surface of the contact arm contacts an electrical pad on a device to be tested when the probe card is lowered toward the device.

6. The probe card of claim 5, wherein:
said probe assembly further comprises a second probe,
the device to be tested includes a plurality of electrical pads, and
the first probe and the second probe are configured and dimensioned to contact one of the plurality of electrical pads when the probe card is lowered toward the device.

7. The probe card of claim 5, wherein the contact arm has a straight axis.

8. The probe card of claim 5, wherein the contact arm has a curved axis.

9. The probe card of claim 8, wherein the curved axis of the contact arm is configured and dimensioned to optimize contact between the surface of the contact arm and the electrical pad.

10. The probe card of claim 1, further comprising a plurality of probe assemblies electrically connected to the circuit board and extending downward from a lower surface of the circuit board.

11. The probe card of claim 9, wherein said plurality of probe assemblies are disposed in an annular pattern around a central portion of the circuit board such that the contact arms of the probe assemblies are oriented towards the central portion.

12. The probe card of claim 1, wherein the elongated probe comprises any of tungsten, tungsten-rhenium, beryllium-copper, paliney, and sliver.

13. A method of testing a semiconductor, comprising:
providing a probe card, said probe card comprising a circuit board and a plurality of probe assemblies, each probe assembly comprising at least one elongated probe having a shaft connected at a first end to an electrical contact on the circuit board and extending at an oblique angle relative to a plane of the circuit board, wherein a second end of the elongated probe includes a contact arm angled toward the circuit board with respect to the oblique angle of the shaft;
placing the probe card over a semiconductor device to be tested, said semiconductor device having a plurality of electrically conductive pads;
contacting an outer surface of the contact arm of the probe of each probe assembly against a pad of the semiconductor device; and
transmitting a signal from the probe card to a circuit test apparatus.

14. The method of claim 13, further comprising scrubbing a surface of the pad with an outer surface of the contact arm.
